(19) United States
(12) Patent Application Publication
(10) Pub. No.: US 2024/0259034 A1
(43) Pub. Date: Aug. 1, 2024

(54) COMPRESSION OF A UNIVARIATE TIME-SERIES DATASET USING MOTIFS

(71) Applicant: HEWLETT PACKARD ENTERPRISE DEVELOPMENT LP, Spring, TX (US)

(72) Inventors: MANTEJ SINGH GILL, Bangalore (IN); Dhamodhran SATHYANARAYANAMURTHY, Bangalore (IN); Madhusoodhana Chari SESHA, Bangalore (IN); Anil BABULAL, Bangalore (IN)

(21) Appl. No.: 18/160,063

(22) Filed: Jan. 26, 2023

(51) Int. Cl. H03M 7/30

(52) U.S. Cl. CPC H03M 7/6011; H03M 7/3073

(57) ABSTRACT

Systems and methods are provided for compressing a time-series dataset from a monitored device into a compressed dataset representation. Using an unsupervised machine learning model, the system may group a contiguous set of datapoints of the time-series dataset and group, using a distance algorithm, the first cluster to a first motif. A compressed dataset representation can be generated using a plurality of motifs, including the first motif, that is stored in place of the time-series dataset. This can allow the time-series dataset to be replaced with the compressed dataset representation, illustrating an overall, abstracted definition of the time-series dataset rather than the individual data points.

### BACKGROUND

As the complexity, size, and processing capacity of computer systems increase, processes performed by these computer systems continue to grow as well. Monitoring systems have grown in popularity to try to manage the applications executed by the computer systems and increase the overall efficiency of the computer systems. However, this is a difficult task. Data is created at ever increasing rates that make it difficult to review. When the review of the data is passed to a third party, the data received by the third party may not have access to all of the environmental data at the computer system.

### BRIEF DESCRIPTION OF THE DRAWINGS

The present disclosure, in accordance with one or more various embodiments, is described in detail with reference to the following figures. The figures are provided for purposes of illustration only and merely depict typical or example embodiments.

FIG. 1 illustrates an action label computer system, monitored device, and user devices, in accordance with some examples of the disclosure.

FIG. 2 illustrates a process for generating and comparing univariate time-series datasets, in accordance with some examples of the disclosure.

FIG. 3 provides an example of time-series data, in accordance with some examples of the disclosure.

FIG. 4 provides an example of minima and maxima of the time-series data, in accordance with some examples of the disclosure.

FIG. 5 provides an example of time-series data with the outlier identified, in accordance with some examples of the disclosure.

FIG. 6 provides an example of time-series data with clusters identified, in accordance with some examples of the disclosure.

FIG. 7 illustrates a process for generating one or more clusters data, in accordance with some examples of the disclosure.

FIG. 8 provides an example of repopulated datasets with different accuracy values, in accordance with some examples of the disclosure.

FIG. 9 is an example computing component that may be used to implement various features of embodiments described in the present disclosure.

FIG. 10 depicts a block diagram of an example computer system in which various of the embodiments described herein may be implemented.

The figures are not exhaustive and do not limit the present disclosure to the precise form disclosed.

### DETAILED DESCRIPTION

Certain types of structured data encountered by a server, such as sensor data, are time-series in nature. This poses a challenge since time-series data often comprise a large volume of data in a format that is difficult for a human to understand, including professionals like data center administrators. Analytics teams, in addition to data center administrators, can face the same challenge while trying to apply analytics to time-series data. Hence, there is a need to find solutions that can help identify the regions of interest, repeating patterns, anomalies, and trends in time-series data.

To help understand time-series data, systems may illustrate the data over time on a graph. For example, a simple time-series dataset may include data points corresponding with a central processing unit (CPU) utilization (e.g., illustrated as a percentage of CPU utilization while executing at system level or user level). The CPU utilization for a personal computer, for example, may be generated where the utilization of the CPU is recorded every second of every day. When the time-series dataset is plotted on a graph that maps time (x-axis) versus utilization (y-axis), the graph may illustrate spikes or dips in the CPU utilization over time. In other words, applications may be executed (e.g., a spike in CPU utilization) or the CPU may remain idle (e.g., a dip in CPU utilization).

When the graph is analyzed by data center administrators, analytics teams, or algorithmically, the spikes and dips in the graph help identify areas where CPU utilization can run more efficiently. For example, when CPU utilization is less than a minimum threshold value (e.g., 10%), the CPU can execute new applications efficiently because the CPU is not being excessively used to execute other processes. Yet, when CPU utilization is greater than a maximum threshold value (e.g., 90%), the CPU may respond by running the new applications slower, causing general inefficiencies in the use of the personal computer. To increase efficiency of the CPU, new applications may be executed when the CPU utilization is less than the minimum threshold value and new applications may avoid being executed when the CPU utilization is greater than the maximum threshold value.

The graph can also be analyzed for patterns over time. In this example, the spikes and dips can identify when the application uses more or fewer resources during its execution, like CPU utilization. The spikes and dips corresponding with the single application over time may correspond with the application's data signature, such that when the application runs in the future, the CPU utilization for executing the application can adhere to the application's data signature and corresponding time-series dataset that the application had generated during the previous execution.

Continuing with this simplified example, the time-series dataset may be provided to a second computer. The second computer may analyze the time-series dataset of the first computer to determine patterns of CPU utilization in the time-series dataset. The second computer can then associate the patterns with data signatures of multiple applications executed by the CPU. In this sense, the second computer can determine when particular applications are executed by the CPU (at the first computer) without having access to an application list, timing of when particular applications are executed, or even the particular components of the computer system associated with the CPU.

Expanding on this simplified example, the CPU may be part of a monitored distributed system with several monitored devices (e.g., an information technology (IT) data center) and the second computer may be a system for optimizing operation of the monitored device(s). The time-series dataset can comprise information from one of the monitored devices that is in addition to (or other than) CPU utilization, including any time-series dataset that corresponds with a use of a sensor incorporated with the monitored device. The system may receive the time-series dataset from a sensor of a monitored device (e.g., the sensor, group of sensors, monitored computer, etc.). The data may comprise an univariate time-series dataset.

To facilitate analysis of the time-series dataset of the monitored device and optimize the use of the monitored system, the system may group the time-series dataset into a plurality of clusters. For example, a set of five time-series dataset entries may correspond with the execution of a single application at the beginning of each hour throughout the day (e.g., corresponding with an automated system check process). Each of these activations may cause a spike in the CPU utilization of the monitored device. The system can identify a pattern of spikes in the time-series dataset and group each spike in the dataset as a cluster that corresponds with the same activity at the monitored device. The time-series dataset may correspond with a plurality of these clusters across several time intervals.

To further help with analytics and improving system utilization of the monitored device, the system may identify similarities across the plurality of clusters and combine a subset of the plurality of clusters based on data signature similarities. The combined pattern identified in the similarities across the clusters are referred to as “motifs.”

The identified similarities of contiguous datapoints across multiple clusters may be determined using various methods. For example, the system may implement an unsupervised machine learning model that is trained to identify and group a contiguous set of datapoints of the time-series dataset into a first cluster. In some examples, the unsupervised machine learning model is trained to identify similar data signatures in each cluster and match the data signatures between clusters in order to form the plurality of motifs. In either sense, the system may extract the motifs from the univariate time-series dataset (e.g. using a customized K-Means algorithm or other clustering algorithm for extracting). The extraction may identify and cluster similar contiguous datapoints and data patterns in the univariate time-series dataset, and output the motifs (e.g., representative of repeated patterns and subsequences).

Once the motifs are generated, a compressed dataset representation may be stored in accordance with a data schema format (e.g., in a JSON format or in a time-series data store). Since the motifs can define patterns in the data (e.g., corresponding with data signatures of applications at the monitored device), the patterns, rather than the individual points of data, may be stored in the dataset representation in accordance with the data schema format. In other words, the dataset representation may represent the entire time-series dataset in a compressed format to take up a reduced memory capacity. Once the dataset representation for each motif is generated, the dataset representation may be used to generate a new, compressed dataset that uses less memory. The compressed dataset may be stored in place of the original univariate time-series dataset, and the original univariate time-series dataset may be deleted to conserve memory space.

The properties of the data schema may include, for each data point in the motif, a unique identifier, time start, time stop, and number of points that are defined for the motif. The data schema may also define the frequency of each of the data points and the closest members of the data points in the motif.

The number of properties or values may be stored in a data structure, like an array data structure. The data structure may include the dataset representation for each motif and may be adjusted using an accuracy value. The accuracy value may be set by a system administrator to identify the number of parameters to define for the dataset representation of each motif. A larger accuracy value (e.g., greater than or in excess of a threshold accuracy value) may define more detail in the dataset representation with greater accuracy between the repopulated time-series dataset and the original time-series dataset, which may result in a larger memory space required to store the dataset representation and repopulated data. A smaller accuracy value (e.g., less than the threshold accuracy value) may define less detail in the dataset representation with less accuracy between the repopulated time-series dataset and the original time-series dataset, which may result in less memory space required to store the dataset representation and repopulated data.

Using the dataset representation formatted in accordance with the data schema, the original time-series dataset may be replaced with a compressed version of the dataset, such that the compressed dataset representation is stored in place of the time-series dataset. This replacement of the time-series dataset with the compressed dataset representation can help achieve an overall, abstracted definition of the original time-series dataset rather than the individual data points.

In some examples, a repopulated dataset may be generated based on the dataset representation. For example, the dataset representation for the particular motif may be used to generate a repopulated dataset, which creates a different dataset than the original one, with a plurality of data points across an x-axis (time) and y-axis (computational value). The repopulated dataset may have some loss in comparison to the original dataset, but the general pattern of the original dataset is identifiable in the repopulated dataset. The accuracy value of the compression and decompression ratio may be altered by the user (e.g., using the accuracy value). This way, the system achieves a lossy compression of the original time-series dataset.

In some examples, the repopulated time-series dataset can be generated, in part, by inserting a representative dataset based on the metadata describing the first motif. The representative dataset may be inserted at a time-based index of a cluster grouped into the first motif.

In some examples, the repopulated time-series dataset can be used to forecast future behavior of the monitored device. For example, the predicted data pattern identified in each of the motifs can correspond with a future behavior, resulting in a predicted future pattern that will continue into the future that complies with the previous time-series dataset.

In some examples, forecasting the future behavior of the monitored device comprises inputting the repopulated time-series dataset into an algorithm that generates future datapoint predictions for time-series datasets. The future datapoint predictions may comply with the pattern identified in the compressed dataset representation for the motif.

After the repopulated dataset is generated using the dataset representation, the system can compare how well the compression worked using a trained machine learning model (e.g., for research and confirmation purposes). For example, the system can provide the original time-series dataset and the repopulated dataset to the trained machine learning model to determine the accuracy reduction and file size reduction between the two. One example of the comparison between the two files resulted in a data file size reduction from 19 kb to 2 kb with only a 1.1 mean accuracy loss.

Technical improvements are realized throughout the disclosure. For example, the original time-series dataset discussed herein can be generated by various components of a server (e.g., sensors, processors, etc.) and grow to be humongous in size. This gives rise to a series of problems related to storing these types of datasets, including physical computing memory that grows into large data lakes and the requirement of high bandwidth for transmitting such large amounts of data throughout the system. The disclosed technology can reduce an amount of data stored and analyzed by the system, resulting in improved computing performance using less memory space. This is especially beneficial for computational features that are generated to work with the time-series data discussed herein.

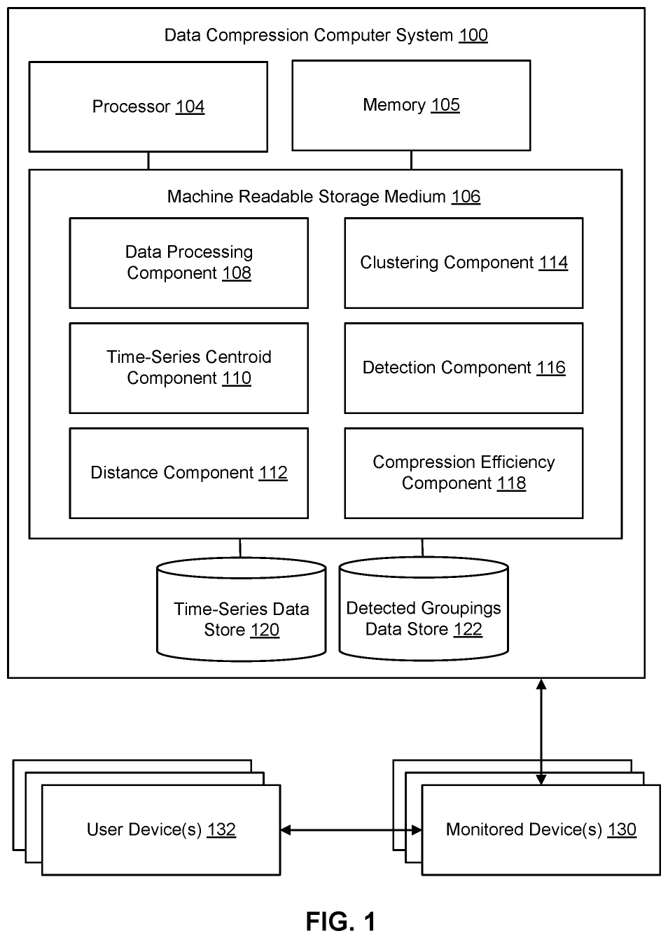

FIG. 1 illustrates a computer system, monitored device, and user devices, in accordance with some examples of the disclosure. In this example, the computer system, illustrated as a special purpose computer system, is labeled as data compression computer system 100. Data compression computer system 100 is configured to interact with monitored device(s) 130 using processor 104, memory 105, and machine readable storage medium 106. Monitored device(s) 130 may interact with one or more user device(s) 132. Data compression computer system 100 may be implemented as a cloud system, data center computer server, as a service, or the like, although such limitations are not required with each embodiment of the disclosure.

Processor 104 may comprise a general-purpose or special-purpose processing engine such as, for example, a microprocessor, controller, or other control logic. Processor 104 may be connected to a bus, although any communication medium can be used to facilitate interaction with other components of data compression computer system 100 or to communicate externally.

Memory 105 may comprise random-access memory (RAM) or other dynamic memory for storing information and instructions to be executed by processor 104. Memory 105 might also be used for storing temporary variables or other intermediate information during execution of instructions to be executed by processor 104. Memory 105 may also comprise a read only memory (“ROM”) or other static storage device coupled to a bus for storing static information and instructions for processor 104.

Machine readable storage medium 106 is configured as a storage device that may comprise one or more interfaces, circuits, and modules for implementing the functionality discussed herein. Machine readable storage medium 106 may carry one or more sequences of one or more instructions processor 104 for execution. Such instructions embodied on machine readable storage medium 106 may enable interaction with monitored device(s) 130 to perform features or functions of the disclosed technology as discussed herein. For example, the interfaces, circuits, and modules of machine readable storage medium 106 may comprise, for example, data processing component 108, time-series centroid component 110, distance component 112, clustering component 114, detection component 116, and compression efficiency component 118.

Data processing component 108 is configured to receive a time-series dataset and store the data in time-series data store 120. The time-series dataset may be received from a sensor of monitored device 130 and comprise various data signatures at different times. In some examples, the data received from monitored device 130 is limited to what a third party responsible for monitored device 130 is willing to provide. As such, a complete data history or components of the data may not be available when the time-series dataset is received.

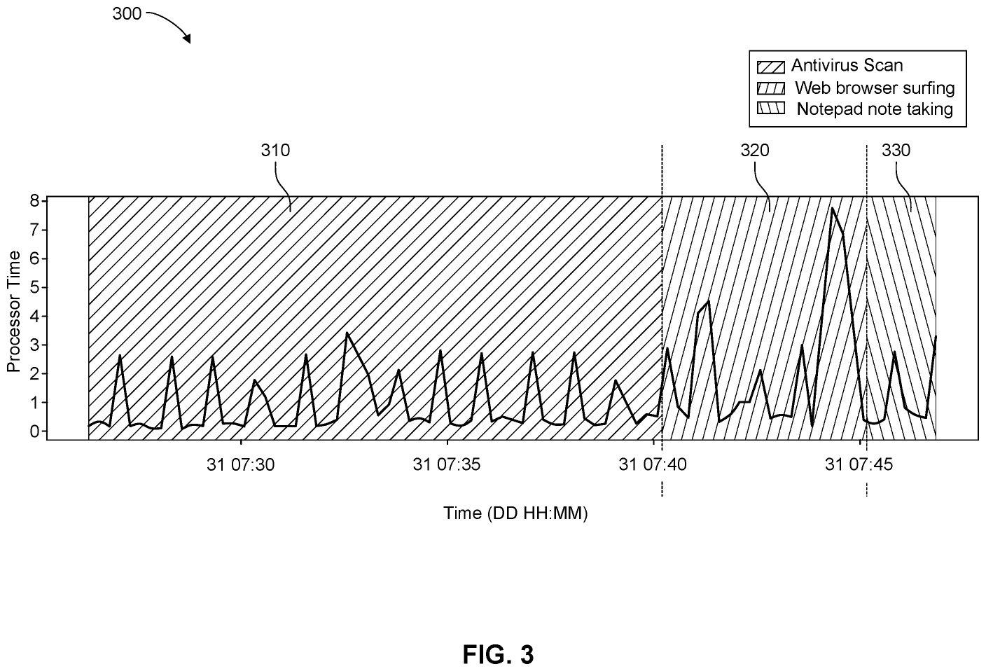

Illustrative examples of time-series datasets are provided. For example, the time-series dataset may correspond with monitored device 130 of a server's input power supply, where input power is provided to the server and sampled at an hourly basis. Another example of a time-series dataset corresponds with processor utilization as the processor is executing instructions for a plurality of software applications, as illustrated with FIG. 3.

Time-series centroid component 110 is configured to determine each centroid of the dataset in anticipation for grouping a contiguous set of datapoints in the data as a first cluster in a plurality of clusters. For example, an unsupervised machine learning model may group the contiguous set of datapoints of the time-series dataset into a first cluster by algorithmically determining the centroid of each contiguous grouping.

The centroids can be initialized using various methods, including a random selection (e.g., a random selection of data points in the received dataset), trained machine learning model, a K-Means cluster algorithm or K-Means++(e.g., by assigning each data point to the cluster with the nearest mean, not minimum/maximum), or by initializing the centroids with outlier points in a customized K-Means cluster algorithm.

In some examples, the clustering algorithm (e.g., a custom K-means algorithm) can be configured to analyze a small subset of the univariate time-series dataset to find local minima and maxima of subsets of the time-series dataset, which can then be associated with a nearest centroid using a skewed Euclidean distance function. This creates some number of clusters, after which, the position of those nearest centroids are calculated again until the data associated with a centroid no longer changes, but rather remains consistent. These become the clusters that are analyzed to identify the aforementioned motifs.

The customized K-Means cluster algorithm may consider the linear fashion that the time-series dataset was recorded in determining each cluster centroid (e.g., contiguous data points). In this sense, time-series centroid engine 110 can group data points that are near in time to each other so they are more likely to be grouped with other readings from the same application, which are stored in detected groupings data store 122. The clusters may comprise centroids, outlier points, and local maxima and local minima. The local local maxima and local minima may be determined to segregate the cluster into smaller clusters, where each smaller cluster can include one significant minima or maxima point.

To find the local minima and maxima on a very small subset of time-series data, time-series centroid engine 110 may use an outlier centroid initialization method or other distance algorithm. For example, first, time-series centroid engine 110 may assume the recently found centroids are k in number. Next, each data point may be associated with the nearest centroid (e.g., using the skewed Euclidean distance function). This will divide the data points into k clusters. With the clusters, then, time-series centroid engine 110 may re-calculate the position of centroids using the skewed Euclidean distance function or other distance algorithm. Any of these steps may be repeated until there are no more changes in the membership of the data points, including dividing the data points into k clusters and calculating the position of centroids using the skewed Euclidean distance function, until there are no more changes. Time-series centroid engine 110 may provide or output the data points with cluster memberships.

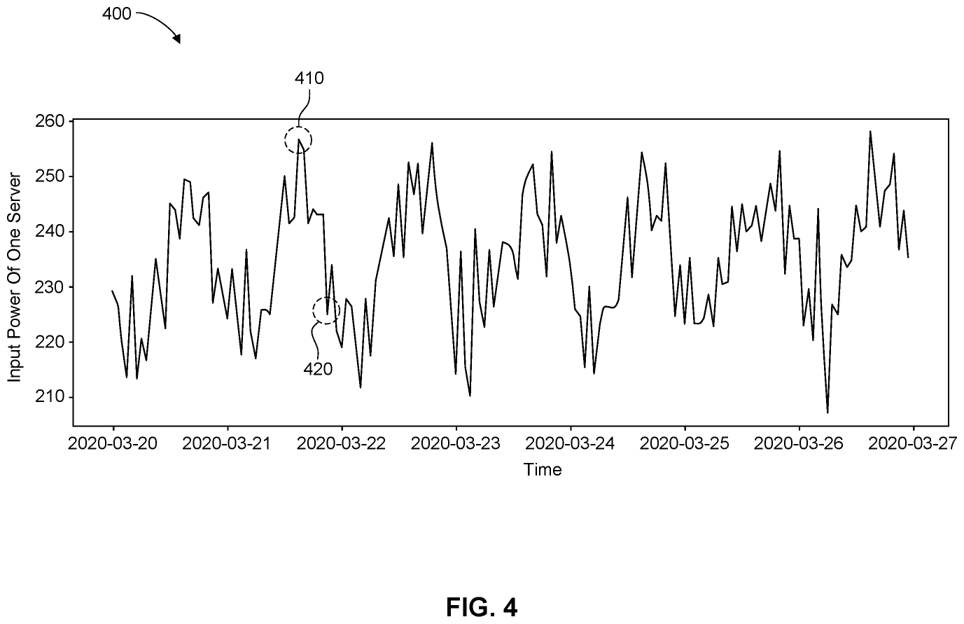

In some examples, contrary to a K-Means random centroid initialization method, time-series centroid engine 110 may determine the number of clusters in an automated and dynamic process. The clusters may not be defined manually. In other words, the number of clusters may be based on the number of maxima and minima points in the time-series dataset that were each grouped as a contiguous set of datapoints of the time-series dataset. Illustrative examples of minima and maxima are provided in FIG. 4.

In some examples, the minima and maxima determined by time-series centroid engine 110 may correspond with actual values from the time-series dataset. The centroid of the cluster may not be chosen from a value that is not included with the dataset (e.g., a mean or average value). Rather, the minima and maxima may correspond with actual data points received from monitored device 130.

Distance component 112 is configured to determine a distance between each of the data points and centroids in the clusters, with respect to the time-series constraint (e.g., along a linear time series). This may improve standard distance functions that may wrongly cluster data points without respect to the linear inherency of time-series data.

The distance formula may determine an amount of change in the time axis (e.g., x-axis) as weighed less compared to the same amount of change on the performance metric axis (e.g., y-axis) so that data points can be clustered following the time axis. One example of a genre of distance formula that can be used is:

$$d = \sqrt{{( {x}_{2} - {x}_{1} )}^{2} + {( {y}_{2} - {y}_{1} )}^{4}}$$

Where “4” may be replaced with an “n” value that is an even number, and greater than or equal to 4. The value may be configurable and customized by a user operating user device 132. This value may be an exponential multiplier of the “y” portion of the formula, which is usually set to a fraction value. When the fraction value is raised to a higher power “n,” the “y” portion of the formula may become smaller. More weight may correspond with the x-axis, which corresponds with the time values and can group the time-series data along the linear path.

Clustering engine 114 is configured to determine one or more clusters. For example, clustering engine 114 may receive the local minima and maxima of subsets of the time-series dataset and the nearest centroid (determined from time-series centroid engine 110). The two datasets may be correlated to form a plurality of clusters, then the position of the nearest centroids may be calculated again until the calculated centroid no longer changes, but rather remains consistent. These become the clusters that are analyzed to identify the motifs, where additional clusters may be grouped with existing motifs that already contain similar clusters.

Detection engine 116 is configured to implement dynamic time warping (DTW) process on the defined clusters to detect similarities between the clusters (e.g., in terms of the data points forming a spike, dip, or other shape within each cluster) and generate one or more motifs. The DTW process can calculate an optimal match between two time-series datasets by measuring the similarity between the two datasets along the linear time sequence. The optimal match may satisfy various restrictions including, for example, every index from the first sequence will be matched with one or more indices from the other sequence, and vice versa, the first index from the first sequence will be matched with the first index from the other sequence (but it does not have to be its only match), the last index from the first sequence will be matched with the last index from the other sequence (but it does not have to be its only match), or the mapping of the indices from the first sequence to indices from the other sequence will be monotonically increasing, and vice versa. The optimal match may also satisfy a minimal cost, where the cost is computed as the sum of absolute differences, for each matched pair of indices, between their values. The similar clusters may be grouped in a motif.

In some examples, detection engine 116 may include a parameter, “c”, which decides the minimum threshold for accepting if two subsequences are similar or not. The threshold value “c” may be inversely proportional to the compression ratio. In other words, for a higher compression ratio, the value of “c” will be lower.

The results may be stored as an in-memory object, including detected groupings data store 122. The dataset may comprise each motifs' metadata along with the indices of the similar subsequences for each motif. The metadata may comprise, for example, values along the x-axis (time) and y-axis (computational value) and indices of the closest or contiguous datapoint members of sequences for the application at the monitored device. The compressed dataset representation may store this or other metadata, which can describe each of the plurality of motifs and time-based indices of clusters grouped into each respective motif.

Additional details regarding analytical operations, output, and actions corresponding with the time series datasets described herein is provided in U.S. patent application Ser. No. 17/991,500 (Docket: P169908US; 61CT-361397) which is herein incorporated by reference in its entirety for all purposes.

Compression efficiency component 118 is configured to access detected groupings data store 122 and determine a dataset representation of each of the plurality of motifs, where the dataset representation is determined in accordance with a pre-defined data schema. The data schema may correspond with a format for defining values of a time-series dataset. The values corresponding with the data schema may create, in the aggregate, a dataset representation of a motif in the plurality of motifs that can be stored in an array data structure.

The data schema may correspond with a particular data format (e.g., JSON format) that defines data properties of the motif. For example, the data schema may comprise a type of the data structure (e.g., an array of type “object”), properties including datapoint, frequency, and closest members, and whether the particular property is required or not. The properties may include a type (e.g., object), unique identifier (e.g., integer value), time start (e.g., string of characters or integer value), time stop (e.g., string of characters or integer value), and number of points.

Compression efficiency component 118 may also generate a dataset representation of each of the plurality of motifs using the data schema. The dataset representation may identify values for each property of the data schema. For example, for a particular motif, the data may generally include ten spikes within ten seconds. The dataset representation for the particular motif may include properties for “spikes” and “frequency” and each property may be populated with a corresponding value of the ten spikes within ten seconds. The dataset representation for the particular motif may be stored in the format corresponding with the data schema.

The dataset representation may correspond with a compressed dataset or metadata of the dataset. In other words, using the dataset representation of each of the plurality of motifs, the original time-series dataset that was used to generate the plurality of motifs may be compressed in a different format corresponding with the data schema. The dataset representation of each of the plurality of motifs may be loaded into the memory as a “compressed” time-series dataset in the format of the data schema.

Compression efficiency component 118 may also use the dataset representation to generate a repopulated time-series dataset. For example, a new time-series dataset or “repopulated” time-series dataset may be constructed by generating data points corresponding explicitly with the dataset representation. The repopulated dataset may be based explicitly on the dataset representation and not from the original dataset. The number of data points in the repopulated dataset may increase with a larger accuracy value, as further discussed herein. In other words, the repopulated dataset may be different than the original time-series dataset with less accuracy than the original.

In some examples, the original time-series dataset may be deleted and only the dataset representation corresponding with the compressed dataset may be stored. This may be implemented because the dataset representation can be used to create a repopulated dataset. In either example, the dataset representation in the format of the data schema for the motif may be stored, either in place of the original time-series dataset or to supplement it.

In some examples, after the repopulated dataset is generated, the system can compare how well the compression worked through a trained machine learning model (e.g., for research and confirmation purposes). The trained machine learning model may be implemented using any time-series forecasting machine learning model, including a model served via a REST API endpoint or known models like FBProphet, SARIMA/SARIMAX, Holt-Winter-ES, and Gated Recurrent Unit (GRU) Network. Various models are provided for illustrative purposes and should not be limiting to the disclosure. These and other models have appropriate training time and size to work with the techniques of the present disclosure. In one example, the train-test split was 80-20 percent.

FBProphet is open-source software. FBProphet is a procedure for forecasting time-series data based on an additive model where non-linear trends are fit with yearly, weekly, and daily seasonality, plus holiday effects. FBProphet can work well with time series that have strong seasonal effects and several seasons of historical data. FBProphet is robust to missing data and shifts in the trend, and typically handles outliers well.

SARIMA is a class of statistical models for analyzing and forecasting time-series data. SARIMA is a generalization of the simpler AutoRegressive Moving Average and adds the notion of integration. Parameters of the SARIMA model are defined as follows: p is the number of lag observations included in the model, also called the lag order; d is the number of times that the raw observations are differenced, also called the “degree of differencing”; q is the size of the moving average window, also called the order of the moving average. The python package pmdarima (Auto-ARIMA) can be used to find the right set of (p, d, q) (P, D, Q) values that exhibit a low AIC (Akaike information criterion) value for each server.

Holt-Winters Exponential Smoothing (ES) can be used for forecasting time-series data that exhibits both a trend and a seasonal variation. Holt-Winters-ES can be a powerful prediction algorithm despite being a relatively simple model. Holt-Winters-ES can handle the seasonality in the data set just by calculating the central value and then adding or multiplying the central value to the slope and seasonality, given the right set of parameters for choosing:

$$level {L}_{t} = α ( {y}_{t} - S \text{?} ) + ( 1 - α ) ( {L}_{t - 1} + {b}_{t - 1} ) ; \\ trend {b}_{t} = β ( {L}_{t} - {L}_{t - 1} ) + ( 1 - β ) {b}_{t - 1} , \\ seasonal S \text{?} = γ ( {y}_{t} - {L}_{t} ) + ( 1 - γ ) S \text{?} \\ forecast F \text{?} = {L}_{t} + kb \text{?} + S \text{?}$$

$$\text{?} \text{indicates text missing or illegible when filed}$$

Gated Recurrent Unit (GRU) Network is a gating mechanism in recurrent neural networks (RNNs) that uses connections through a sequence of nodes to perform machine learning tasks associated with memory. GRU can also solve the vanishing gradient problem that comes with a standard recurrent neural network (RNN). To solve the vanishing gradient problem of a standard RNN, GRU uses an update gate and reset gate. Essentially the gates are two vectors that decide what information should be passed to the output. The gates are trained to keep information from long past time periods, without washing the information through time or removing information that is irrelevant to the prediction.

Various machine learning models such as the above can learn and predict the accuracy reduction and file size reduction in the future time periods. A check can be included for whether the forecast was successful and, if so, the forecast (e.g., for the next 20 or 30 days in non-limiting examples) is passed to other system components.

In an illustrative example, the system can provide the original time-series dataset and the repopulated dataset to one of the trained machine learning models above to determine the accuracy reduction and file size reduction between the two. One example of the comparison between the two files resulted in a data file size reduction from 19 kb to 2 kb with only a 1.1 mean accuracy loss.

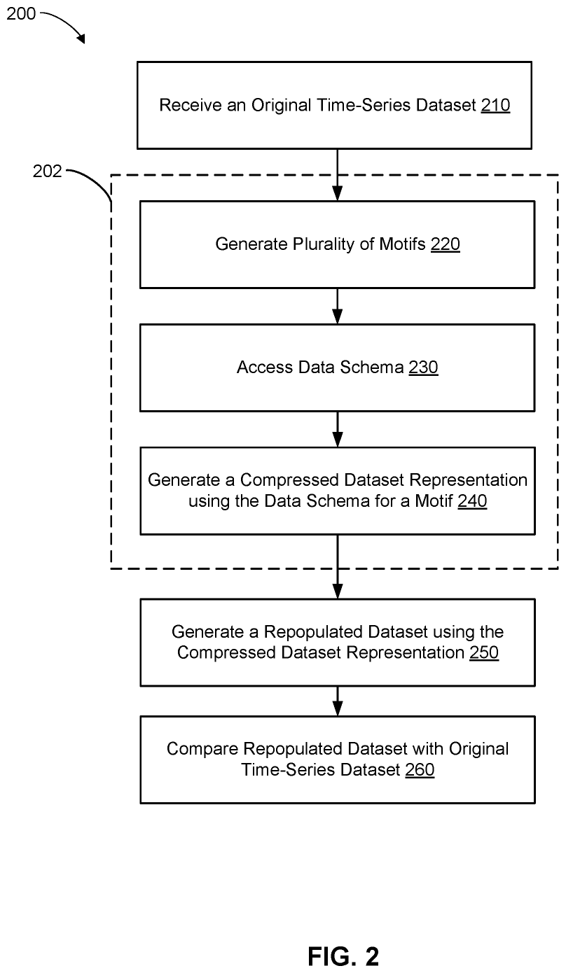

FIG. 2 illustrates a process for generating and comparing univariate time-series datasets, in accordance with some examples of the disclosure. Data compression computer system 100 of FIG. 1 may be configured to execute machine-readable instructions to perform the process 200 described herein, including implementing a data compression process 202 of time-series dataset as illustrated in at least blocks 220-240.

At block 210, an original time-series dataset may be received. For example, data compression computer system 100 may receive the time-series dataset that includes data points corresponding with a monitored device or a monitored distributed system with several monitored devices. The time-series dataset can comprise CPU utilization, use of a sensors incorporated with the monitored device, or other univariate time-series data.

At block 220, a plurality of motifs may be generated. For example, data compression computer system 100 may group the time-series dataset into a plurality of clusters, including identifying a pattern of spikes or dips in the original time-series dataset and grouping each cluster as corresponding with the same activity at the monitored device. The original time-series dataset may correspond with a plurality of these clusters across time intervals. The system may further identify similarities across the plurality of clusters and combine a subset of the plurality of clusters based on data signature similarities to form a plurality of motifs using an unsupervised machine learning model, as further described herein.

In some examples, the plurality of motifs may be previously generated and a cluster may be added to one or more of the motifs. For example, a contiguous set of datapoints of the original time-series dataset may be grouped into a first cluster. The grouping may be executed using any method discussed herein, including using an unsupervised machine learning model. The cluster may then be grouped into a first motif when the cluster is similar to other clusters of the first motif. The grouping may be executed using any method discussed herein, including using a distance algorithm.

At block 230, a data schema may be accessed. For example, data compression computer system 100 may access a data schema corresponding with time-series dataset. The parameters of the data schema may comprise a type of the data structure (e.g., an array of type “object”), properties including datapoint, frequency, and closest members, and whether the particular property is required or not. Each datapoint property of the data schema may comprise type (e.g., object), unique identifier (e.g., integer value), time start (e.g., string of characters or integer value), time stop (e.g., string of characters or integer value), and number of points.

At block 240, a compressed dataset representation for a motif may be generated using the data schema. The compressed dataset representation may identify values for each property of the motif. For example, for a particular motif, the data of the monitored device may include ten spikes within ten seconds, in general. The data schema may include properties for “spikes” and “frequency,” and the compressed dataset representation of the particular motif may define the values for those properties (e.g., of the ten spikes within ten seconds). Using this compressed dataset representation of the motif, the detail of the particular motif may be abstracted and stored in the format corresponding with the data schema.

The level of detail of the compressed dataset representation may correspond with an accuracy value, discussed herein as parameter “c”, which decides the minimum threshold for accepting if two subsequences are similar or not. To do this, the accuracy value corresponds with a minimum threshold value for accepting if two subsequences are similar or not and the parameter “c” may be inversely proportional to the compression ratio. In other words, for a higher compression ratio, the parameter “c” would be lower. The accuracy value may be set by a system administrator.

In some cases, a larger accuracy value (in excess of a threshold accuracy value) may correspond with more detail in the compressed dataset representation and greater accuracy between the repopulated time-series dataset and the original time-series dataset, which may result in a larger memory space required to store the compressed dataset representation and repopulated data. A smaller accuracy value (less than the threshold accuracy value) may correspond with less detail in the compressed dataset representation and less accuracy between the repopulated time-series dataset and the original time-series dataset, which may result in less memory space required to store the compressed dataset representation and repopulated data.

Multiple dataset representations may be generated, where each compressed dataset representation corresponds with each of the plurality of motifs. In other words, the original time-series dataset that was used to generate the plurality of motifs may be compressed and represented as one or more dataset representations.

At block 202, comprising blocks 220-240, the processes defined herein may generate a compressed dataset representation defining a compressed dataset of the original time-series dataset. The compressed time-series dataset may be defined by the compressed dataset representation that can be used to generate repopulated data with similar, repeating data patterns as the original time-series dataset but with fewer anomalies and distinctions found in the original time-series dataset.

At block 250, a repopulated dataset may be generated based on the compressed dataset representation. For example, the dataset representation for the particular motif may be used to generate a repopulated dataset, which creates a different dataset than the original time-series dataset, with a plurality of data points across an x-axis (time) and y-axis (computational value). The repopulated dataset may have some accuracy loss in comparison to the original time-series dataset, but the general pattern of the original time-series dataset is identifiable in the repopulated dataset.

At block 260, the repopulated dataset may be compared with the original time-series dataset. For example, the original time-series dataset may correspond with the data points, before the compression, of the monitored distributed system with several monitored devices, and the repopulated dataset may be generated from the dataset representation. The comparison can show the accuracy reduction and file size reduction between the two.

FIG. 3 provides an example of time-series data, in accordance with some examples of the disclosure. In example 300, the processor time is identified for a monitored device that runs three different applications during 15 seconds, illustrated as first application 310 (e.g., an antivirus scan), second application 320 (e.g., a web browser video), and third application 330 (e.g., a notepad application). Each of the applications run without overlapping processor time to illustrate the distinctions between the signatures. In this example, the applications 310, 320, and 330 were run independently, exclusively, and consecutively to observe the difference in the time-series signature of each application.

FIG. 4 provides an example of minima and maxima of the time-series data, in accordance with some examples of the disclosure. In example 400, an illustrative time-series dataset is provided with an illustrative maxima data point 410 and an illustrative minima data point 420. For example, each instance where the points in the dataset, along a linear progression of the time series, changes direction (e.g., progresses from increasing to decreasing, or from decreasing to increasing, etc.), a minima point or a maxima point may be identified. In some examples, time-series centroid engine 110 is configured to store the minima or maxima in time-series data store 120.

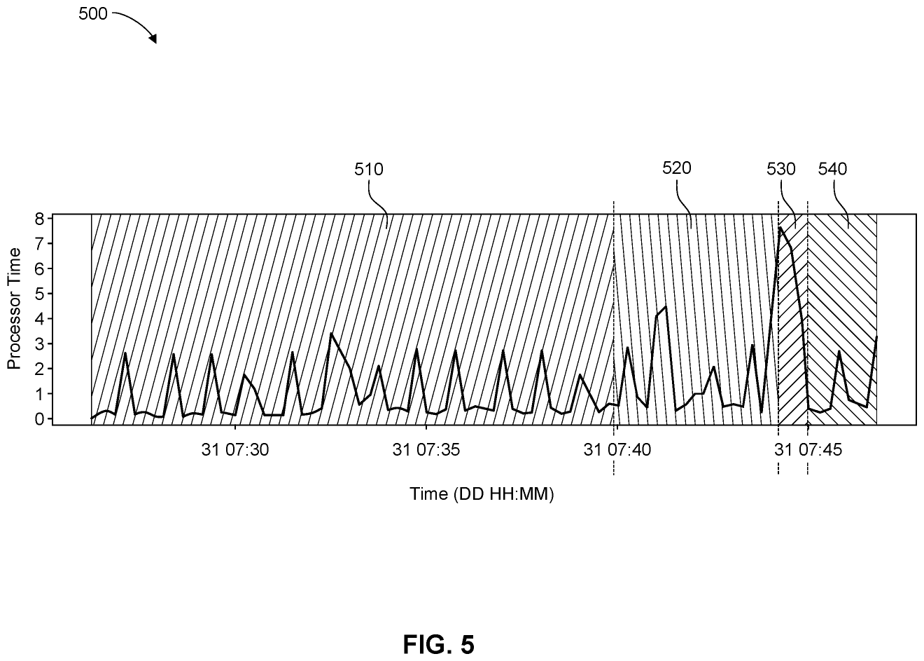

FIG. 5 provides an example of time-series data with the outlier identified, in accordance with some examples of the disclosure. In example 500, the time-series data is repeated from example 300 of FIG. 3, where the processor time is identified for a monitored device that runs three different applications during 15 seconds, including first application 510 (e.g., an antivirus scan), second application 520 (e.g., a web browser video), and third application 540 (e.g., a notepad application). Additionally, an outlier is identified between the second application and third application, illustrated as outlier 530.

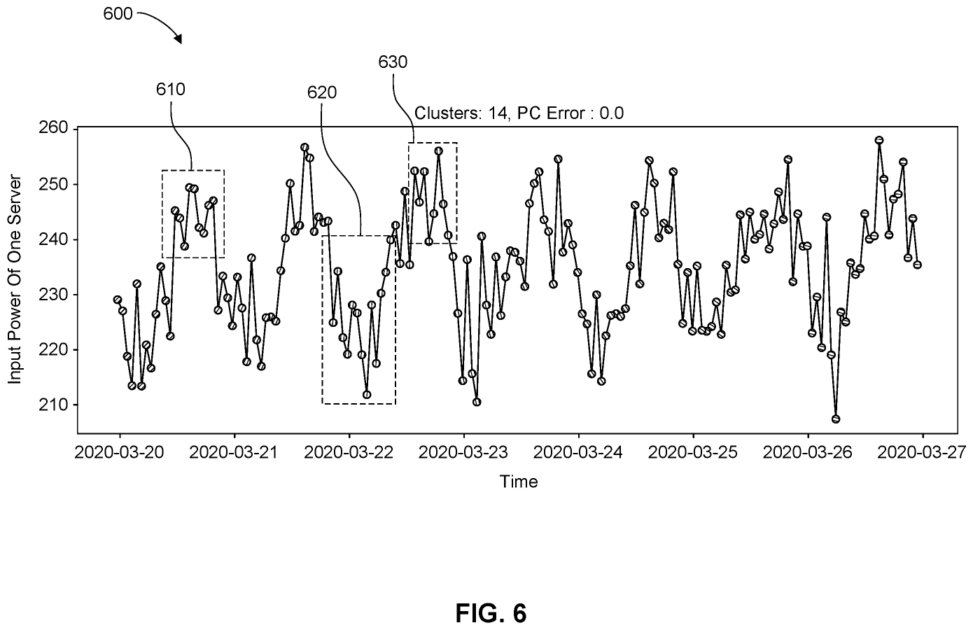

FIG. 6 provides an example of time-series data with clusters identified, in accordance with some examples of the disclosure. In example 600, the time-series data is analyzed and grouped as a plurality of clusters, where the data signature similarities are used to form a plurality of motifs using an unsupervised machine learning model. Illustrative clusters are provided, shown as first cluster 610 and second cluster 620. These clusters may help create labeled time-series data, where each cluster corresponds with a different label (e.g., different application or data signature, etc.). A similar cluster to first cluster 610 is identified as a third cluster 630, which have a similar data signature determined using the unsupervised machine learning model. The model may be trained to identify similar data signatures in each cluster and match the data signatures.

In this context, each cluster of similar curves can be grouped into a motif. As discussed herein, each motif may represent a repeated pattern and subsequence of data points that are grouped into each cluster. The distance algorithms discussed herein may help find curve similarities between the clusters. As illustrated in FIG. 5, multiple similar shapes of data points in first application 510 (e.g., an antivirus scan) are each motifs of the dataset. Multiple motifs may be combined to form a shapelet, which may correspond with the entire dataset corresponding with first application 510.

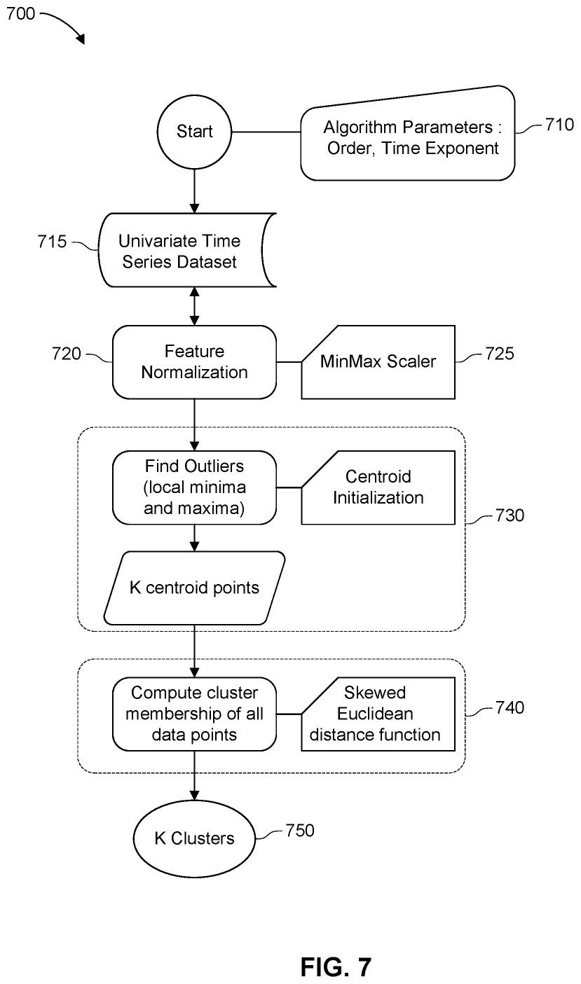

The clusters may be formed using various processes, including the process illustrated in FIG. 7 to implement a custom K-Means clustering algorithm with outlier centroid initialization and a skewed Euclidean distance function. In illustrative example 700, clustering engine 114 of FIG. 1 may perform one or more steps to determine the plurality of clusters.

At block 710, the input may include algorithm parameters, some of which may be altered by a user operating user device 132 of FIG. 1. The input may include, for example, input data points D, an order parameter θ, and a time component N in order to generate data points with cluster memberships.

At block 715, the time-series dataset may be received (e.g., by data processing component 108 of FIG. 1). The time-series dataset may be received from a sensor of monitored device 130 and comprise various data signatures at different times.

At block 720, the data may be processed, including implementing a feature normalization on the time-series dataset. For example, feature normalization may scale the individual samples of data from the time-series dataset to have common and consistent unit measurements.

At block 725, the data may be further processed, including implementing a scaler process on the time-series dataset. The scaler process can help improve wide variations in the data to create small standard deviations of features and preserve zero entries in sparse data.

At block 730, clustering component 114 of FIG. 1 may receive the local minima and maxima using the outlier centroid initialization method to obtain centroids c1, c2, . . . ck. As discussed with the process performed by distance component 112 of FIG. 1, the order parameter may be adjusted to determine various centroids.

At block 740, for each data point xi, find the nearest centroid (c1, c2, . . . ck) using the Skewed Euclidean distance function and assign the point to that cluster. The Skewed Euclidean distance function may comprise the distance formula as discussed with distance component 112 of FIG. 1.

At block 750, repeat block 730 and block 740 with different values of the order parameter θ and time component N. These groups of values become the clusters that are analyzed to identify the motifs and stored in detected groupings data store 122 of FIG. 1.

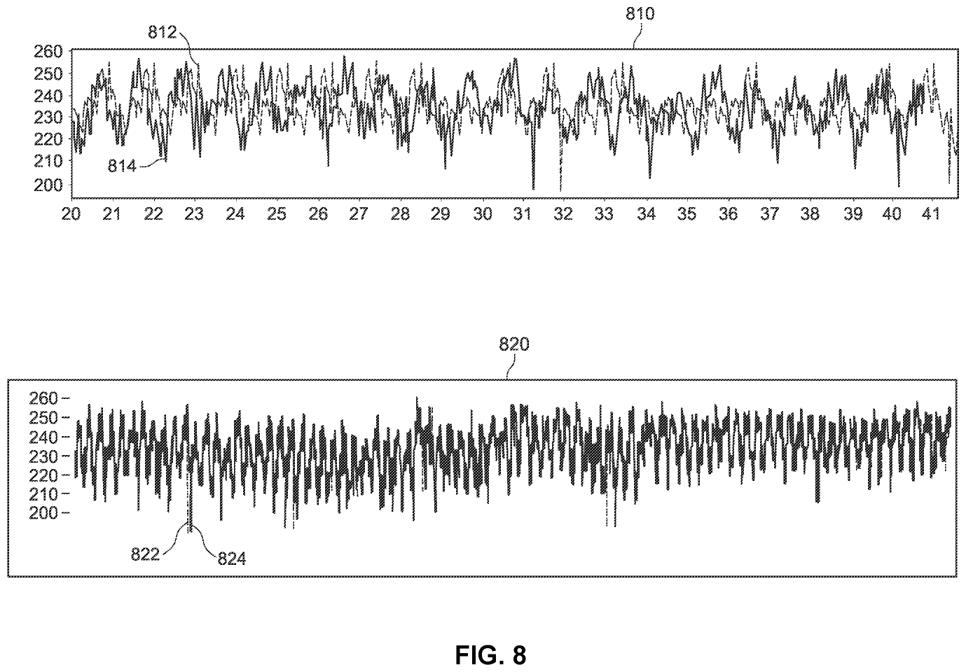

FIG. 8 provides an example of repopulated datasets with different accuracy values, in accordance with some examples of the disclosure. Each of these charts plot the data points for a time-series dataset, either generated by the original monitored device (e.g., as the original time-series dataset) or generated as a repopulated dataset by the data compression computer system 100 of FIG. 1 using a dataset representation for a motif at a particular accuracy value. As shown, the dataset representations used to create each of the first repopulated dataset and the second repopulated dataset are different with different accuracy values.

In example 810, a first original time-series dataset 812 is compared with a first repopulated dataset 814 that was generated from a dataset representation at a first accuracy value. The accuracy value in this example is less than the accuracy threshold, resulting in more memory saved and less accuracy when compared to the original dataset. In this example, first repopulated dataset 814 uses only 500 datapoints and saves 90% of the memory usage (e.g., file size reduction) in comparison with the original time-series dataset 812.

In example 820, a second original time-series dataset 822 is compared with a second repopulated dataset 824 that was generated from a dataset representation at a second accuracy value. The accuracy value in this example is greater than the accuracy threshold, resulting in less memory saved and greater accuracy when compared to the original dataset. The parameter “c” is set to 0.75. The second repopulated dataset 824 uses 2000 datapoints and saves 30% of the memory usage (e.g., file size reduction) in comparison with the original time-series dataset 822. The parameter “c” is set to 0.40. The achieved compression ratio for each example is provided below.

| | | | | | | | | | | | | Achieved |
|---|---|---|---|---|---|---|---|---|---|---|---|---|
| | | | | | | | | | | | | compression |
| | No. of | Value | Original Dataset | | | | Compressed Dataset | | | | | ratio |
| Server | Data- | of ‘c’ | File Size | | | | File Size | | | | | (original size/ |
| no. | points | parameter | on disk | MAE | MAPE | RMSE | on disk | | MAE | MAPE | RMSE | compressed size) |
| 1 | 500 | 0.75 | 19 kb | 5.887 | 0.0256 | 7.4585 | 2 | kb | 6.9107 | 0.0303 | 8.9591 | 9.5 |
| | 2000 | 0.4 | 76 kb | 5.1326 | 0.0215 | 6.3261 | 50 | kb | 5.0490 | 0.0211 | 6.2632 | 1.52 |
| 2 | 500 | 0.75 | 19 kb | 4.8485 | 0.0216 | 6.1002 | 3 | kb | 8.8395 | 0.0391 | 10.5777 | 6.34 |
| | 2000 | 0.4 | 76 kb | 5.2309 | 0.0221 | 6.4301 | 50 | kb | 6.0514 | 0.0256 | 7.4583 | 1.52 |
| 3 | 500 | 0.75 | 19 kb | 6.0538 | 0.0307 | 7.5988 | 3 | kb | 8.719 | 0.0454 | 10.5552 | 6.34 |
| | 2000 | 0.4 | 76 kb | 7.4204 | 0.0383 | 9.3472 | 54 | kb | 7.3526 | 0.0379 | 9.2331 | 1.41 |

It should be noted that the terms “optimize,” “optimal” and the like as used herein can be used to mean making or achieving performance as effective or perfect as possible. However, as one of ordinary skill in the art reading this document will recognize, perfection cannot always be achieved. Accordingly, these terms can also encompass making or achieving performance as good or effective as possible or practical under the given circumstances, making or achieving performance better than that which can be achieved with other settings or parameters, or making or achieving performance better than a pre-defined threshold.

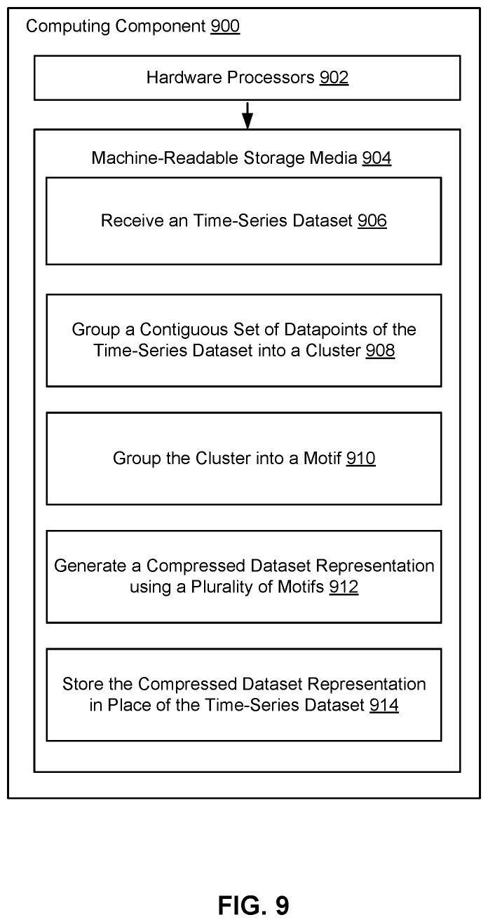

FIG. 9 illustrates an example computing component that may be used to implement a compression of a time-series dataset using motifs, in accordance with various embodiments. Referring now to FIG. 9, computing component 900 may be, for example, a server computer, a controller, or any other similar computing component capable of processing data. In the example implementation of FIG. 9, the computing component 900 includes a hardware processor 902, and machine-readable storage medium for 904.

Hardware processor 902 may be one or more central processing units (CPUs), semiconductor-based microprocessors, and/or other hardware devices suitable for retrieval and execution of instructions stored in machine-readable storage medium 904. Hardware processor 902 may fetch, decode, and execute instructions, such as instructions 906-914, to control processes or operations for implementing the dynamically modular and customizable computing systems. As an alternative or in addition to retrieving and executing instructions, hardware processor 902 may include one or more electronic circuits that include electronic components for performing the functionality of one or more instructions, such as a field programmable gate array (FPGA), application specific integrated circuit (ASIC), or other electronic circuits.

A machine readable storage medium, such as machine readable storage medium 904, may be any electronic, magnetic, optical, or other physical storage device that contains or stores executable instructions. Thus, machine readable storage medium 904 may be, for example, Random Access Memory (RAM), non-volatile RAM (NVRAM), an Electrically Erasable Programmable Read-Only Memory (EEPROM), a storage device, an optical disc, and the like. In some embodiments, machine readable storage medium 904 may be a non-transitory storage medium, where the term “non-transitory” does not encompass transitory propagating signals. As described in detail below, machine readable storage medium 904 may be encoded with executable instructions, for example, instructions 906-914.

Hardware processor 902 may execute instruction 906 to receive a time-series dataset. The time-series dataset may be received from a sensor of a monitored device. For example, the time-series dataset may comprise various data signatures at different times. In some examples, the data received from monitored device is limited to what a third party responsible for monitored device is willing to provide and may be limited from a complete data history.

Hardware processor 902 may execute instruction 908 to group a contiguous set of datapoints of the time-series dataset into a cluster. The grouping may be implemented using an unsupervised machine learning model that is trained to group a continuous set of datapoints int a cluster. For example, the method may group the time-series dataset into a first cluster of a plurality of clusters.

Hardware processor 902 may execute instruction 910 to group the first cluster into a first motif. For example, the method may group the first cluster into the first motif due to the first cluster being similar to other clusters of the first motif. The similar may be determined using any of the methods described herein, including by identifying similarities in data signatures. In some examples, the method may determine each centroid of the dataset in determining the similarities in the data and grouping the cluster with the motif.

The centroids can be initialized using various methods, including a customized K-Means cluster algorithm. The customized K-Means cluster algorithm may consider the linear fashion that the time-series dataset was recorded in determining each cluster centroid. The method may initialize the centroids of each cluster with outlier points to determine local maxima and local minima points that correspond with actual values from the time-series dataset. With this, the time-series data may be segregated into smaller clusters areas, where each smaller cluster can include one significant minima or maxima point.

The method may also determine a distance between each of the data points and centroids, with respect to the time-series constraint (e.g., along a linear time-series), which can help improve standard distance functions that may wrongly cluster data points without respect to the linear inherency of time-series data. The distance formula may determine an amount of change in the time axis (e.g., x-axis) as weighed less compared to the same amount of change on the performance metric axis (e.g., y-axis) so that data points can be clustered following the time axis (e.g., using the formula described herein).

Hardware processor 902 may execute instruction 912 to generate a compressed dataset representation using a plurality of motifs. This dataset representation may include metadata of the plurality of motifs according to a pre-defined data schema. In some examples, the dataset representation may correspond to a compressed dataset that is stored in accordance with the data schema format (e.g., in a JSON format or in a time-series data store). Since the motifs can define patterns in the data (e.g., corresponding with data signatures of applications at the monitored device), the patterns, rather than the individual points of data, may be stored in the compressed dataset representation.

Hardware processor 902 may execute instruction 914 to store the compressed dataset representation in place of the time-series dataset. In some examples, the original time-series dataset may be deleted. For example, the compressed dataset representation that uses less memory may be stored in place of the original univariate time-series dataset. This replacement may help recover and conserve memory space.

In some examples, instruction 914 may be replaced or supplemented with other features and functions described herein. For example, computing component 900 may be configured to generate a repopulated time-series dataset using the dataset representation, provide the repopulated time-series dataset and the original time-series dataset to a trained supervised machine learning model, and determine an accuracy reduction and a file size reduction between the repopulated time-series dataset and the original time-series dataset. In some examples, the differences between the file sizes may be correlated with adjusting the parameter “c” value to keep more or less accuracy in the dataset.

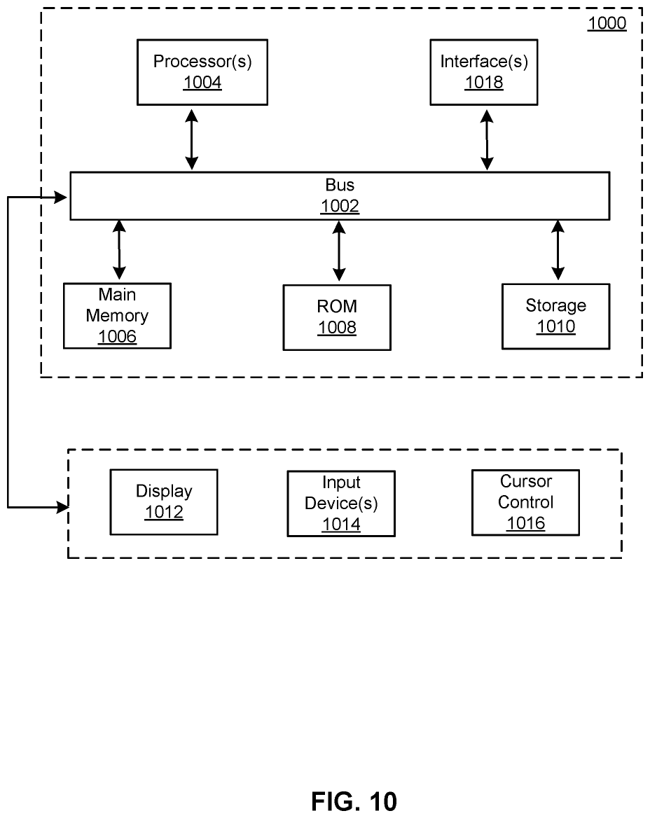

FIG. 10 depicts a block diagram of an example computer system 1000 in which various of the embodiments described herein may be implemented. The computer system 1000 includes a bus 1002 or other communication mechanism for communicating information, one or more hardware processors 1004 coupled with bus 1002 for processing information. Hardware processor(s) 1004 may be, for example, one or more general purpose microprocessors.

The computer system 1000 also includes a main memory 1006, such as a random access memory (RAM), cache and/or other dynamic storage devices, coupled to bus 1002 for storing information and instructions to be executed by processor 1004. Main memory 1006 also may be used for storing temporary variables or other intermediate information during execution of instructions to be executed by processor 1004. Such instructions, when stored in storage media accessible to processor 1004, render computer system 1000 into a special-purpose machine that is customized to perform the operations specified in the instructions.

The computer system 1000 further includes a read only memory (ROM) 1008 or other static storage device coupled to bus 1002 for storing static information and instructions for processor 1004. A storage device 1010, such as a magnetic disk, optical disk, or USB thumb drive (Flash drive), etc., is provided and coupled to bus 1002 for storing information and instructions.

The computer system 1000 may be coupled via bus 1002 to a display 1012, such as a liquid crystal display (LCD) (or touch screen), for displaying information to a computer user. An input device 1014, including alphanumeric and other keys, is coupled to bus 1002 for communicating information and command selections to processor 1004. Another type of user input device is cursor control 1016, such as a mouse, a trackball, or cursor direction keys for communicating direction information and command selections to processor 1004 and for controlling cursor movement on display 1012. In some embodiments, the same direction information and command selections as cursor control may be implemented via receiving touches on a touch screen without a cursor.

The computing system 1000 may include a user interface module to implement a GUI that may be stored in a mass storage device as executable software codes that are executed by the computing device(s). This and other modules may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables.

In general, the word “component,” “engine,” “system,” “database,” data store,” and the like, as used herein, can refer to logic embodied in hardware or firmware, or to a collection of software instructions, possibly having entry and exit points, written in a programming language, such as, for example, Java, C or C++. A software component may be compiled and linked into an executable program, installed in a dynamic link library, or may be written in an interpreted programming language such as, for example, BASIC, Perl, or Python. It will be appreciated that software components may be callable from other components or from themselves, and/or may be invoked in response to detected events or interrupts. Software components configured for execution on computing devices may be provided on a computer readable or machine readable storage medium, such as a compact disc, digital video disc, flash drive, magnetic disc, or any other tangible medium, or as a digital download (and may be originally stored in a compressed or installable format that requires installation, decompression or decryption prior to execution). Such software code may be stored, partially or fully, on a memory device of the executing computing device, for execution by the computing device. Software instructions may be embedded in firmware, such as an EPROM. It will be further appreciated that hardware components may be comprised of connected logic units, such as gates and flip-flops, and/or may be comprised of programmable units, such as programmable gate arrays or processors.

The computer system 1000 may implement the techniques described herein using customized hard-wired logic, one or more ASICs or FPGAS, firmware and/or program logic which in combination with the computer system causes or programs computer system 1000 to be a special-purpose machine. According to one embodiment, the techniques herein are performed by computer system 1000 in response to processor(s) 1004 executing one or more sequences of one or more instructions contained in main memory 1006. Such instructions may be read into main memory 1006 from another storage medium, such as storage device 1010. Execution of the sequences of instructions contained in main memory 1006 causes processor(s) 1004 to perform the process steps described herein. In alternative embodiments, hard-wired circuitry may be used in place of or in combination with software instructions.

The term “non-transitory media,” and similar terms, as used herein refers to any media that store data and/or instructions that cause a machine to operate in a specific fashion. Such non-transitory media may comprise non-volatile media and/or volatile media. Non-volatile media includes, for example, optical or magnetic disks, such as storage device 1010. Volatile media includes dynamic memory, such as main memory 1006. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, and networked versions of the same.

Non-transitory media is distinct from but may be used in conjunction with transmission media. Transmission media participates in transferring information between non-transitory media. For example, transmission media includes coaxial cables, copper wire and fiber optics, including the wires that comprise bus 1002. Transmission media can also take the form of acoustic or light waves, such as those generated during radio-wave and infra-red data communications.

The computer system 1000 also includes a communication interface 1018 coupled to bus 1002. Communication interface 1018 provides a two-way data communication coupling to one or more network links that are connected to one or more local networks. For example, communication interface 1018 may be an integrated services digital network (ISDN) card, cable modem, satellite modem, or a modem to provide a data communication connection to a corresponding type of telephone line. As another example, communication interface 1018 may be a local area network (LAN) card to provide a data communication connection to a compatible LAN (or WAN component to communicated with a WAN). Wireless links may also be implemented. In any such implementation, communication interface 1018 sends and receives electrical, electromagnetic or optical signals that carry digital data streams representing various types of information.

A network link typically provides data communication through one or more networks to other data devices. For example, a network link may provide a connection through local network to a host computer or to data equipment operated by an Internet Service Provider (ISP). The ISP in turn provides data communication services through the world wide packet data communication network now commonly referred to as the “Internet.” Local network and Internet both use electrical, electromagnetic or optical signals that carry digital data streams. The signals through the various networks and the signals on network link and through communication interface 1018, which carry the digital data to and from computer system 1000, are example forms of transmission media.

The computer system 1000 can send messages and receive data, including program code, through the network(s), network link and communication interface 1018. In the Internet example, a server might transmit a requested code for an application program through the Internet, the ISP, the local network and the communication interface 1018.

The received code may be executed by processor 1004 as it is received, and/or stored in storage device 1010, or other non-volatile storage for later execution.

Each of the processes, methods, and algorithms described in the preceding sections may be embodied in, and fully or partially automated by, code components executed by one or more computer systems or computer processors comprising computer hardware. The one or more computer systems or computer processors may also operate to support performance of the relevant operations in a “cloud computing” environment or as a “software as a service” (SaaS). The processes and algorithms may be implemented partially or wholly in application-specific circuitry. The various features and processes described above may be used independently of one another, or may be combined in various ways. Different combinations and sub-combinations are intended to fall within the scope of this disclosure, and certain method or process blocks may be omitted in some implementations. The methods and processes described herein are also not limited to any particular sequence, and the blocks or states relating thereto can be performed in other sequences that are appropriate, or may be performed in parallel, or in some other manner. Blocks or states may be added to or removed from the disclosed example embodiments. The performance of certain of the operations or processes may be distributed among computer systems or computers processors, not only residing within a single machine, but deployed across a number of machines.

As used herein, a circuit might be implemented utilizing any form of hardware, software, or a combination thereof. For example, one or more processors, controllers, ASICs, PLAS, PALs, CPLDs, FPGAs, logical components, software routines or other mechanisms might be implemented to make up a circuit. In implementation, the various circuits described herein might be implemented as discrete circuits or the functions and features described can be shared in part or in total among one or more circuits. Even though various features or elements of functionality may be individually described or claimed as separate circuits, these features and functionality can be shared among one or more common circuits, and such description shall not require or imply that separate circuits are required to implement such features or functionality. Where a circuit is implemented in whole or in part using software, such software can be implemented to operate with a computing or processing system capable of carrying out the functionality described with respect thereto, such as computer system 1000.

As used herein, the term “or” may be construed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps.

Terms and phrases used in this document, and variations thereof, unless otherwise expressly stated, should be construed as open ended as opposed to limiting. Adjectives such as “conventional,” “traditional,” “normal,” “standard,” “known,” and terms of similar meaning should not be construed as limiting the item described to a given time period or to an item available as of a given time, but instead should be read to encompass conventional, traditional, normal, or standard technologies that may be available or known now or at any time in the future. The presence of broadening words and phrases such as “one or more,” “at least,” “but not limited to” or other like phrases in some instances shall not be read to mean that the narrower case is intended or required in instances where such broadening phrases may be absent.

What is claimed is:

1. A system comprising:
one or more processors; and
a machine readable storage medium storing instructions that, when executed by the one or more processors, cause the system to:
receive a time-series dataset from a monitored device;
group a contiguous set of datapoints of the time-series dataset into a first cluster using an unsupervised machine learning model;
group, using a distance algorithm, the first cluster into a first motif, wherein the first cluster is grouped into the first motif due to the first cluster being similar to other clusters of the first motif;
generate a compressed dataset representation using a plurality of motifs, including the first motif, wherein the compressed dataset representation includes metadata of the plurality of motifs according to a pre-defined data schema; and
store the compressed dataset representation in place of the time-series dataset.

2. The system of claim 1, wherein the compressed dataset representation includes metadata describing each of the plurality of motifs and time-based indices of clusters grouped into each respective motif.

3. The system of claim 2, the instructions further causing the system to:
generate a repopulated time-series dataset from the compressed dataset representation; and
forecast future behavior of the monitored device using the repopulated time-series dataset.

4. The system of claim 3, wherein the repopulated time-series dataset is generated, in part, by inserting, at a time-based index of a cluster grouped into the first motif, a representative dataset based on the metadata describing the first motif.

5. The system of claim 3, wherein forecasting the future behavior of the monitored device comprises inputting the repopulated time-series dataset into an algorithm that generates future datapoint predictions for time-series datasets.

6. The system of claim 1, wherein the distance algorithm finds curve similarities between clusters.

7. The system of claim 1, wherein the unsupervised machine learning model is trained using a customized K-Means cluster algorithm.

8. A computer-implemented method, comprising:
receiving a time-series dataset from a monitored device;
grouping a contiguous set of datapoints of the time-series dataset into a first cluster using an unsupervised machine learning model;
grouping, using a distance algorithm, the first cluster into a first motif, wherein the first cluster is grouped into the first motif due to the first cluster being similar to other clusters of the first motif;
generating a compressed dataset representation using a plurality of motifs, including the first motif, wherein the compressed dataset representation includes metadata of the plurality of motifs according to a pre-defined data schema; and
storing the compressed dataset representation in place of the time-series dataset.

9. The method of claim 8, wherein the compressed dataset representation includes metadata describing each of the plurality of motifs and time-based indices of clusters grouped into each respective motif.

10. The method of claim 9, further comprising:
generating a repopulated time-series dataset from the compressed dataset representation; and
forecasting future behavior of the monitored device using the repopulated time-series dataset.

11. The method of claim 10, wherein the repopulated time-series dataset is generated, in part, by inserting, at a time-based index of a cluster grouped into the first motif, a representative dataset based on the metadata describing the first motif.

12. The method of claim 10, wherein forecasting the future behavior of the monitored device comprises inputting the repopulated time-series dataset into an algorithm that generates future datapoint predictions for time-series datasets.

13. The method of claim 8, wherein the distance algorithm finds curve similarities between clusters.

14. The method of claim 8, wherein the unsupervised machine learning model is trained using a customized K-Means cluster algorithm.

15. A non-transitory machine-readable storage medium comprising instructions executable by a processor, the instructions programming the processor to:
receive a time-series dataset from a monitored device;
group a contiguous set of datapoints of the time-series dataset into a first cluster using an unsupervised machine learning model;
group, using a distance algorithm, the first cluster into a first motif, wherein the first cluster is grouped into the first motif due to the first cluster being similar to other clusters of the first motif;
generate a compressed dataset representation using a plurality of motifs, including the first motif, wherein the compressed dataset representation includes metadata of the plurality of motifs according to a pre-defined data schema; and
store the compressed dataset representation in place of the time-series dataset.

16. The non-transitory machine-readable storage medium of claim 15, wherein the compressed dataset representation includes metadata describing each of the plurality of motifs and time-based indices of clusters grouped into each respective motif.

17. The non-transitory machine-readable storage medium of claim 16, the instructions further programming the processor to:
generate a repopulated time-series dataset from the compressed dataset representation; and
forecast future behavior of the monitored device using the repopulated time-series dataset.

18. The non-transitory machine-readable storage medium of claim 17, wherein the repopulated time-series dataset is generated, in part, by inserting, at a time-based index of a cluster grouped into the first motif, a representative dataset based on the metadata describing the first motif.

19. The non-transitory machine-readable storage medium of claim 17, wherein forecasting the future behavior of the monitored device comprises inputting the repopulated time-series dataset into an algorithm that generates future datapoint predictions for time-series datasets.

20. The non-transitory machine-readable storage medium of claim 19, wherein the distance algorithm finds curve similarities between clusters.
